(19) United States
(12) Patent Application Publication
(10) Pub. No.: US 2023/0317574 A1
(43) Pub. Date: Oct. 5, 2023

(54) SEMICONDUCTOR PACKAGE SUBSTRATE, SEMICONDUCTOR PACKAGE INCLUDING THE SAME, AND METHOD OF MANUFACTURING THE SEMICONDUCTOR PACKAGE SUBSTRATE

(71) Applicant: HAESUNG DS CO., LTD., Gyeongsangnam-do (KR)

(72) Inventors: Suyoen SON, Gyeonggi-do (KR); Jinwoo LEE, Seoul (JP); Hosang YU, Gyeonggi-do (JP); Jinseop JANG, Seoul (JP)

(21) Appl. No.: 18/064,517

(22) Filed: Dec. 12, 2022

(30) Foreign Application Priority Data
Apr. 5, 2022 (KR) 10-2022-0042147

(51) Int. Cl. H01L 23/495; H01L 23/00; H01L 23/31; H01L 21/48

(52) U.S. Cl. CPC H01L 23/49582; H01L 24/48; H01L 23/3121; H01L 21/4821; H01L 2224/48245

(57) ABSTRACT

The disclosure provides a semiconductor package substrate, a semiconductor package, and a method of manufacturing the semiconductor package substrate. An embodiment of the disclosure provides a semiconductor package substrate including a base substrate including a die pad portion and a lead portion, a metal catalyst layer arranged on the base substrate, and a graphene layer arranged on the metal catalyst layer.

### CROSS-REFERENCE TO RELATED APPLICATIONS

This application is based on and claims priority under 35 U.S.C. § 119 to Korean Patent Application No. 10-2022-0042147, filed on Apr. 5, 2022, in the Korean Intellectual Property Office, the disclosure of which is incorporated by reference herein in its entirety.

### BACKGROUND

### 1. Field

Embodiments of the disclosure relate to a semiconductor package substrate, a semiconductor package including the same, and a method of manufacturing the semiconductor package substrate, and more particularly, to a semiconductor package substrate including a graphene layer as an antioxidant film, a semiconductor package including the semiconductor package substrate, and a method of manufacturing the semiconductor package substrate.

### 2. Description of the Related Art

A semiconductor package substrate is an intermediate part that electrically connects a semiconductor chip to an external device such as a printed circuit board, etc. The semiconductor package substrate may serve to support a semiconductor chip, and the semiconductor chip and the semiconductor package substrate may be electrically connected to each other through wire bonding or a solder bump.

The semiconductor package substrate mainly includes a copper metal such that an oxide film may be generated on the semiconductor package substrate by oxygen and water vapor in the air. In this case, wire bonding may not be possible or a bonding strength may be low. Conventionally, a method of plating precious metal such as silver or gold on the semiconductor package substrate or a method of coating an organic film on the semiconductor package substrate has been introduced to prevent the formation of the oxide film.

However, the method of plating the precious metal may be expensive for entire plating because of the expensive precious metal, and may complicate a process in case of plating of a part where wire bonding is performed.

In the method of coating the organic film, coating to a thickness of several tens of micrometers is performed to sufficiently obtain an antioxidant period, and thus, a wire bonding or solder bump bonding process may not be performed smoothly.

### SUMMARY

Embodiments of the disclosure provide a semiconductor package substrate including a graphene layer as an antioxidant film, and a method of manufacturing the semiconductor package substrate.

Additional aspects will be set forth in part in the description which follows and, in part, will be apparent from the description, or may be learned by practice of the presented embodiments of the disclosure.

According to an aspect of the disclosure, a semiconductor package substrate includes a base substrate including a die pad portion and a lead portion, a metal catalyst layer arranged on the base substrate, and a graphene layer arranged on the metal catalyst layer.

In an embodiment, the base substrate may include a copper (Cu) alloy, and the metal catalyst layer may include at least one of Cu, nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt).

In an embodiment, the base substrate may include a copper (Cu) alloy, and the metal catalyst layer may include Cu of a purity of 99% or higher.

In an embodiment, the metal catalyst layer may be continuously arranged to surround a top surface, a bottom surface, and a side surface of each of the die pad portion and the lead portion.

In an embodiment, the graphene layer may be continuously arranged to surround a top surface, a bottom surface, and a side surface of each of the die pad portion and the lead portion.

According to another aspect of the disclosure, a semiconductor package includes the semiconductor package substrate, a semiconductor chip arranged on the die pad portion, and a bonding wire connecting the semiconductor chip with the lead portion, in which the bonding wire directly contacts the graphene layer.

In an embodiment, a wire pull strength of the bonding wire may be about 3.5 gf to about 5 gf.

In an embodiment, the semiconductor package may further include a mold resin covering the semiconductor chip and the bonding wire.

According to another aspect of the disclosure, a method of manufacturing a semiconductor package substrate includes processing a base metal into a base substrate including a die pad portion and a lead portion, forming a metal catalyst layer on the base substrate, and forming a graphene layer on the metal catalyst layer.

In an embodiment, the base metal may include a copper (Cu) alloy, and the metal catalyst layer may include at least one of Cu, nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt).

In an embodiment, the metal catalyst layer may be continuously formed to surround a top surface, a bottom surface, and a side surface of each of the die pad portion and the lead portion.

In an embodiment, the graphene layer may be continuously formed to surround a top surface, a bottom surface, and a side surface of each of the die pad portion and the lead portion.

In an embodiment, the forming of the graphene layer may include a temperature-boosting operation of placing the base substrate where the metal catalyst layer is formed in a thermal reactor and boosting a temperature inside the thermal reactor to a first temperature and a synthesizing operation of injecting a carbon source while maintaining the first temperature after the temperature-boosting operation.

In an embodiment, the first temperature may be between about 900° C. to about 1500° C.

In an embodiment, a time for maintaining the first temperature in the synthesizing operation may be about 0.5 hour to about 2 hours.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a semiconductor package manufactured using a semiconductor package substrate, according to an embodiment of the disclosure;

FIG. 2 is a schematic cross-sectional view of a semiconductor package substrate, according to an embodiment of the disclosure;

FIG. 3 shows data obtained by analyzing an antioxidant effect of a semiconductor package substrate, according to an embodiment of the disclosure;

FIG. 4 is a flowchart of a method of manufacturing a semiconductor package substrate, according to an embodiment of the disclosure; and

FIGS. 5 to 8 are cross-sectional views sequentially showing a method of manufacturing a semiconductor package substrate.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure may have various modifications thereto and various embodiments, and thus particular embodiments will be illustrated in the drawings and described in detail in a detailed description. Effects and features of the disclosure, and a method of achieving them will be apparent with reference to the embodiments described in detail in conjunction with the drawings. However, the disclosure is not limited to the embodiments disclosed below, but may be implemented in various forms.

Hereinafter, embodiments of the disclosure will be described in detail with reference to the accompanying drawings, and in description with reference to the drawings, the same or corresponding components are given the same reference numerals, and redundant description thereto will be omitted.

In the following embodiments, the terms first, second, etc., have been used to distinguish one component from other components, rather than limiting.

In the following embodiment, singular forms include plural forms unless apparently indicated otherwise contextually.

In the following embodiments, the terms “include”, “have”, or the like, are intended to mean that there are features, or components, described herein, but do not preclude the possibility of adding one or more other features or components.

In the following embodiments, when a portion, such as a film, a region, a component, etc., is present on or above another portion, this case may include not only a case where it is directly on the other portion, but also a case where another film, region, component, etc., is arranged between the portion and the other portion.

In the drawings, the size of components may be exaggerated or reduced for convenience of description. For example, the size and thickness of each component shown in the drawings are shown for convenience of description, and thus the disclosure is not necessarily limited to the illustration.

When a certain embodiment may be implemented otherwise, a particular process order may be performed differently from the order described. For example, two processes described in succession may be performed substantially simultaneously, or may be performed in an order reverse to the order described.

In the following embodiments, when a film, a region, a component, etc., are connected, the case may include not only a case where they are directly connected, but also a case where they are indirectly connected, having another film, region, and component therebetween. For example, herein, when a film, a region, a component, etc., are electrically connected, the case may include not only a case where they are directly electrically connected, but also a case where they are indirectly electrically connected, having another film, region, and component therebetween.

Hereinafter, embodiments of the disclosure will be described in detail with reference to the accompanying drawings, and in description with reference to the drawings, the same or corresponding components are given the same reference numerals, and redundant description thereto will be omitted.

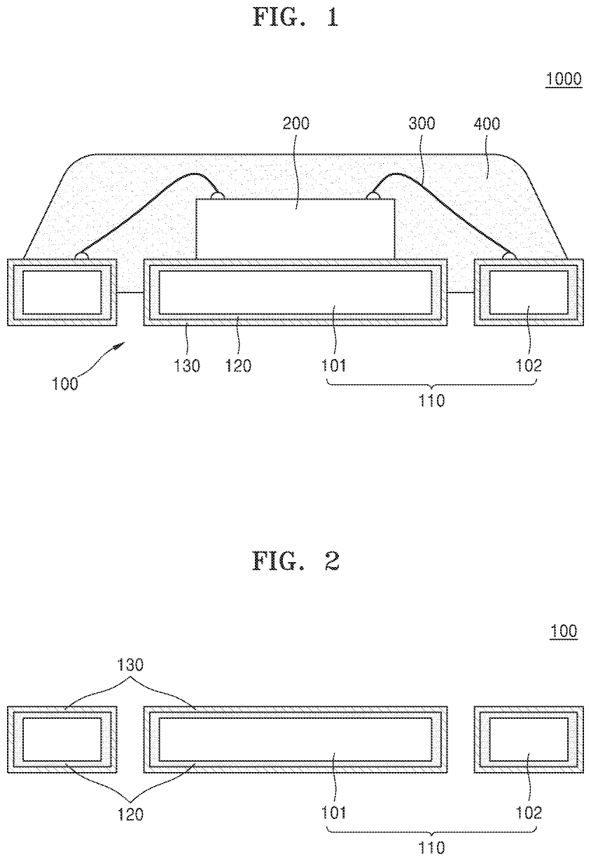

FIG. 1 is a schematic cross-sectional view of a semiconductor package manufactured using a semiconductor package substrate, according to an embodiment of the disclosure. FIG. 2 is a schematic cross-sectional view of a semiconductor package substrate, according to an embodiment of the disclosure.

Referring to FIG. 1, a semiconductor package 1000 according to an embodiment of the disclosure may include a semiconductor package substrate 100, a semiconductor chip 200, bonding wires 300 connecting the semiconductor chip 200 with the semiconductor package substrate 100, and a mold resin 400.

Referring to FIG. 2, the semiconductor package substrate 100 according to an embodiment of the disclosure may include a base substrate 110, a metal catalyst layer 120 arranged on the base substrate 110, and a graphene layer 130 arranged on the metal catalyst layer 120.

The base substrate 110 may include a die pad portion 101 and a lead portion 102. The semiconductor chip 200 may be attached to a top surface of the semiconductor package substrate 100 corresponding to the die pad portion 101. The lead portion 102 may be provided in plural, and the top surface of the semiconductor package substrate 100 corresponding to the lead portion 102 may be connected with the semiconductor chip 200 by the bonding wires 300. Although not shown, a bottom surface of the semiconductor package substrate 100 corresponding to the lead portion 102 may be connected with an external device (not shown) through a solder ball (not shown). Thus, an electric signal output from the semiconductor chip 200 may be transmitted to the external device through the lead portion 102, and an electric signal input from the external device to the lead portion 102 may be transmitted to the semiconductor chip 200.

The base substrate 110 may include a metal material. The base substrate 110 may include a copper (Cu) or Cu alloy material. For example, the base substrate 110 may include Cu as a main material and further include iron, zinc, and/or phosphorus, etc.

In some embodiments, the base substrate 110 may include a Cu alloy including 97.4% of Cu, 2.4% of iron, 0.13% of zinc, and 0.03% of others. The base substrate 110 may be provided to a thickness of about 100 μm to about 150 μm.

The base substrate 110 may be provided in a shape including the die pad portion 101 and the lead portion 102 by processing a base metal of such a metal material.

The metal catalyst layer 120 may be arranged on the base substrate 110. The metal catalyst layer 120 may be introduced to facilitate synthesis of the graphene layer 130 to be used as an antioxidant film. When the base substrate 110 includes a Cu alloy including a material in addition to Cu, a graphene layer of high quality may be difficult to synthesize. In the current embodiment, by introducing the metal catalyst layer 120 of high purity, the graphene layer 130 of high quality may be synthesized.

The metal catalyst layer 120 may include at least one of Cu, nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt).

In some embodiments, the metal catalyst layer 120 may include one of the foregoing materials and may be provided as a single layer of high purity. For example, the metal catalyst layer 120 may include Cu having a purity of 99% or more. Alternatively, the metal catalyst layer 120 may include a structure a single layer having a purity of 99% or higher is stacked. For example, the metal catalyst layer 120 may have various stacked structures such as Cu/Ag, Cu/Au, Ni/Ag, Ni/Au, Pt/Cu, Rh/Ni, etc. The metal catalyst layer 120 may have a thickness of about 1 μm to about 10 μm.

The metal catalyst layer 120 may be formed to at least partially surround a top surface, a bottom surface, and a side surface of the base substrate 110. That is, the metal catalyst layer 120 may be arranged on at least some of a top surface, a bottom surface, and a side surface of the die pad portion 101. The metal catalyst layer 120 may be arranged on at least some of a top surface, a bottom surface, and a side surface of the lead portion 102 of the base substrate 110.

In some embodiments, the metal catalyst layer 120 may be arranged to continuously surround the top surfaces, the bottom surfaces, and the side surfaces of the die pad portion 101 and the lead portion 102 of the base substrate 110. Thus, the graphene layer 130 formed on the metal catalyst layer 120 may be arranged to continuously surround the top surfaces, the bottom surfaces, and the side surfaces of the die pad portion 101 and the lead portion 102 of the base substrate 110.

The graphene layer 130 may be arranged on the metal catalyst layer 120. The graphene layer 130 may form a two-dimensional (2D) planar sheet form through connection of a plurality of carbon atoms by covalent bond, and the carbon atoms connected by covalent bond may form a 6-membered ring as a basic repeating unit, but may further include a 5-membered ring and/or a 7-membered ring. Thus, the graphene layer 130 may include a single layer of carbon atoms (generally, sp2 bond) covalently bonded to each other. However, without being limited thereto, the graphene 130 may have a structure in which a plurality of single layers of 2D planar sheets are stacked. The graphene layer 130 may have various structures that may vary with a content of a 5-membered ring and/or a 7-membered ring included in the graphene layer 130.

A void in a carbon lattice of the graphene layer 130 may be formed smaller than the size of a molecule that causes metal surface oxidation, such as a water molecule. Thus, by forming the graphene layer 130 on the base substrate 110, oxidation of the base substrate 110 may be prevented.

Meanwhile, the graphene layer 130 may be formed to include a grain region having a certain crystal structure as carbon atoms continuously form covalent bond and a grain boundary region where covalent bond between carbon atoms are misaligned and thus broken or other impurities are included. This may mean the antioxidation effect may degrade when many grain boundary regions are formed in the graphene layer 130.

In the current embodiment, the metal catalyst layer 120 is introduced between the base substrate 110 and the graphene layer 130, thereby forming the graphene layer 130 of high quality having many grain regions formed therein and thus maximizing the antioxidation effect.

In some embodiments, the graphene layer 130 may be arranged on the metal catalyst layer 120 to continuously surround the top surfaces, the bottom surfaces, and the side surfaces of the die pad portion 101 and the lead portion 102 of the base substrate 110.

When the graphene layer 130 is formed before formation of the die pad portion 101 and the lead portion 102 and then the base substrate 110 is processed, moisture or outside air may penetrate into the side surface of the die pad portion 101 or the lead portion 102.

In the current embodiment, the graphene layer 130 is formed after the die pad portion 101 and the lead portion 102 are processed, such that the graphene layer 130 may be arranged on the side surfaces of the die pad portion 101 and the lead portion 102 as well as the top surfaces and the bottom surfaces thereof. Thus, there is no space for penetration of moisture or outside air into the base substrate 110, and thus the graphene layer 130 may sufficiently function as an antioxidation film.

Referring back to FIG. 1, the semiconductor chip 200 may be mounted on the top surface of the semiconductor package substrate 100. The semiconductor chip 200 may be arranged on the graphene layer 130 arranged on the die pad portion 101. An organic film layer may be coated onto the graphene layer 130 arranged on the die pad portion 101. The semiconductor chip 200 may be adhered to the graphene layer 130 of the die pad portion 101 through epoxy. In this case, an organic film layer (not shown) including an organic material may be coated onto the graphene layer 130 of the die pad portion 101. The organic film layer may be intended to prevent an epoxy bleed out phenomenon.

The semiconductor chip 200 may be connected through the graphene layer 130 arranged on the lead portion 102 and a bonding wire 300. The bonding wire 300 may be provided as an Au or Cu wire. The bonding wire 300 needs to be firmly bonded to the semiconductor package substrate 100 so as not to suffer from a disconnection problem in future signal transmission.

According to the current embodiment, the graphene layer 130 arranged on the lead portion 102 of the base substrate 110 may improve the reliability of a product due to the excellent property of bonding with the bonding wire 300. In the current embodiment, a wire pull strength of the bonding wire 300 bonded with the lead portion 102 may be about 3.5 gf to about 5 gf.

More specifically, for (Embodiment) where the metal catalyst layer 120 including copper of 1 μm is plated onto the base substrate 110 and the graphene layer 130 is synthesized on the metal catalyst layer 120 and (Comparative Example) where a Cu layer of 1 μm is plated onto the base substrate 110, a gold wire bonding test is performed.

As a result, (Embodiment) shows a bonding success rate of 97% and a good wire pull strength of 4.8 gf. On the other hand, (Comparative Example) shows a bonding success rate of 0%. In (Comparative Example), it is determined that due to generation of an oxide layer, a bonding force between the bonding wire 300 and the semiconductor package substrate is weakened.

The mold resin 400 may encapsulate the top surface of the semiconductor package substrate 100 by covering the semiconductor chip 200 and the bonding wire 300 mounted on the semiconductor package substrate 100. The mold resin 400 may be provided as resin such as an epoxy mold compound.

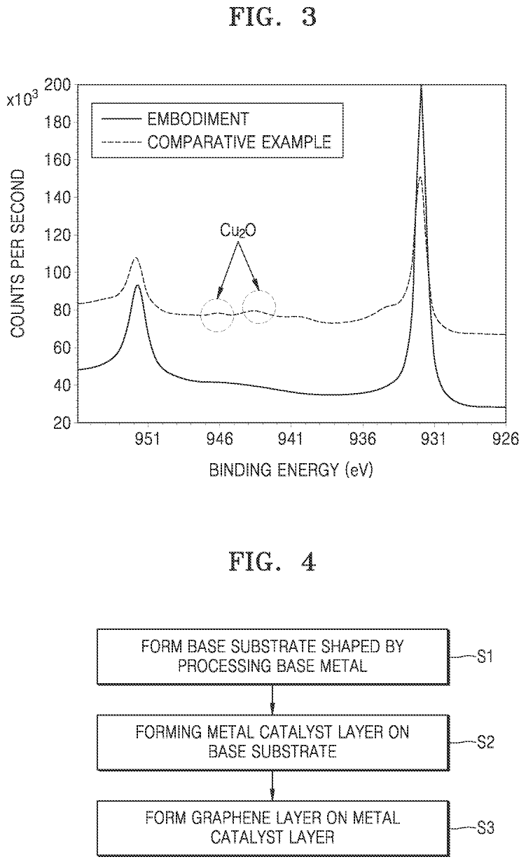

FIG. 3 shows data obtained by analyzing an antioxidant effect of a semiconductor package substrate, according to an embodiment of the disclosure.

In (Embodiment), for a semiconductor package substrate according to the current embodiment, a metal catalyst layer provided as Cu of 1 μm is plated onto a base substrate of a Cu alloy material and a graphene layer is synthesized on the metal catalyst layer. In (Comparative Example), a Cu layer of 1 μm is plated onto a base substrate of a Cu alloy material.

(Embodiment) and (Comparative Example) are taken into an environmental test analyzer chamber of a temperature of 85° C. and a humidity of 85% and are subject to oxidation acceleration processing for 5 hours.

The data of FIG. 3 shows a result of performing analysis with X-ray photoelectron spectroscopy after oxidation acceleration processing. In (Comparative Example), it may be seen that an oxide layer, Cu₂O, is formed based on detection of a weak peak around 946 eV and 943 eV indicating a Cu₂O component, but in (Embodiment), it may be analyzed that an oxide layer is not formed due to non-detection of a peak around 946 eV and 943 eV.

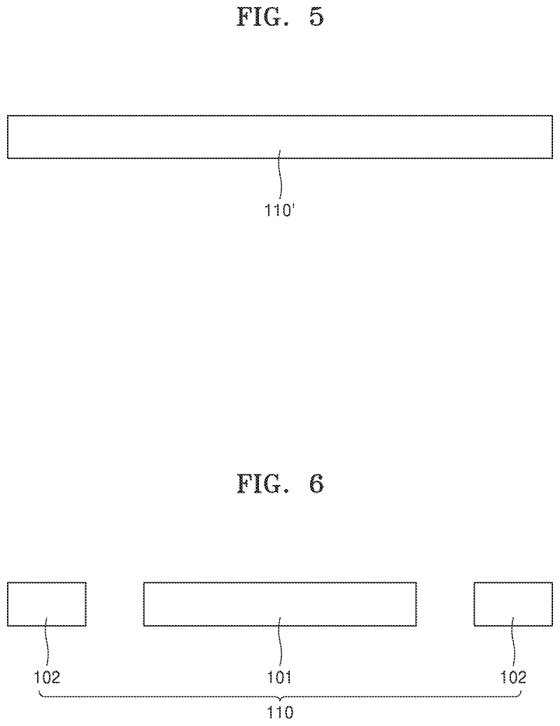

FIG. 4 is a flowchart of a method of manufacturing a semiconductor package substrate, according to an embodiment of the disclosure. FIGS. 5 to 8 are cross-sectional views sequentially showing a method of manufacturing a semiconductor package substrate.

Referring to FIG. 4, a method of manufacturing a semiconductor package substrate according to an embodiment of the disclosure may include operation 51 of forming a base substrate shaped by processing a base metal, operation S2 of forming a metal catalyst layer on the base substrate, and operation S3 of forming a graphene layer on a metal catalyst layer.

Referring to FIG. 5, base metal 110′ including a metal material is provided. The base metal 110′ may include Cu or a Cu alloy material. For example, the base metal 110′ may include Cu as a main material and further include iron, zinc, and/or phosphorus, etc. In some embodiments, the base metal 110′ may include a Cu alloy including 97.4% of Cu, 2.4% of iron, 0.13% of zinc, and 0.03% of others. The base metal 110′ may be provided to a thickness of about 100 μm to about 150 μm.

Next, referring to FIG. 6, the base substrate 110 including the die pad portion 101 and the lead portion 102 may be formed by processing the base metal 110′.

To process the base substrate 110, a photoresist pattern may be formed on the base substrate 110 and then metal etching processing may be performed. The etching processing may be wet processing. Alternatively, to process the base substrate 110, a process of forming a pattern by irradiating a laser beam may be performed. Through this process, the base substrate 110 including the die pad portion 101 and the lead portion 102 may be formed.

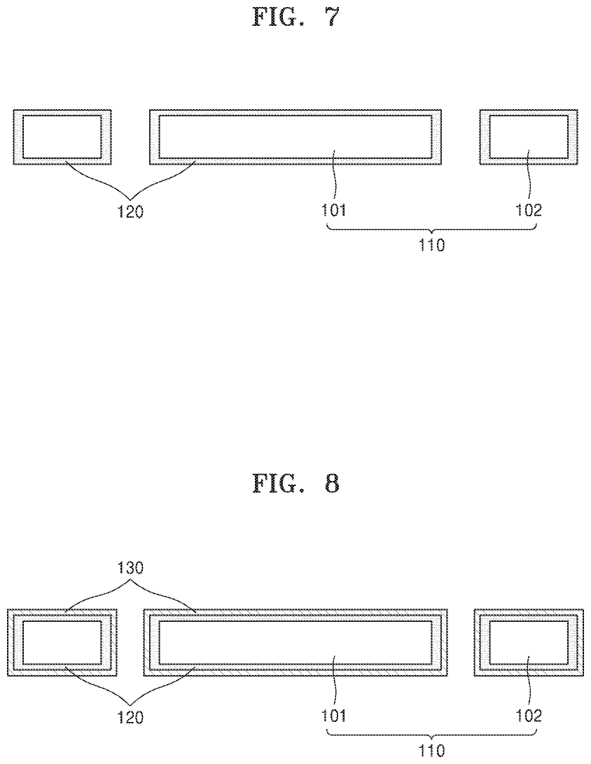

Next, referring to FIG. 7, the metal catalyst layer 120 may be formed on the base substrate 110 in operation S2.

The metal catalyst layer 120 may be formed to at least partially cover the top surface, the bottom surface, and the side surface of the base substrate 110. That is, the metal catalyst layer 120 may be formed to at least partially cover the top surfaces, the bottom surfaces, and the side surfaces of the die pad portion 101 and the lead portion 102. In some embodiments, the metal catalyst layer 120 may be formed to continuously cover the top surfaces, the bottom surfaces, and the side surfaces of the die pad portion 101 and the lead portion 102.

The metal catalyst layer 120 may include at least one of Cu, Ni, Ag, Au, Ti, Co, Ru, Rh, Pd, Hf, Ta, W, Re, Ir, and Pt. The metal catalyst layer 120 may be formed by various plating methods such as electrolytic plating, non-electrolytic plating, etc.

In some embodiments, the metal catalyst layer 120 may include one of the foregoing materials and may be provided as a single layer of high purity. For example, the metal catalyst layer 120 may include Cu having a purity of 99% or more. Alternatively, the metal catalyst layer 120 may include a structure a single layer having a purity of 99% or higher is stacked. For example, the metal catalyst layer 120 may have various stacked structures such as Cu/Ag, Cu/Au, Ni/Ag, Ni/Au, Pt/Cu, Rh/Ni, etc. The metal catalyst layer 120 may have a thickness of about 1 μm to about 10 μm.

Next, referring to FIG. 8, the graphene layer 130 may be synthesized on the metal catalyst layer 120 in operation S3.

Before the graphene layer 130 is synthesized on the metal catalyst layer 120, plasma processing may be performed on or pre-processing for removing a foreign substance may be performed on the surface of the metal catalyst layer 120. Through this processing, an adhesive force between the metal catalyst layer 120 and the graphene layer 130 may be improved.

An operation of forming the graphene layer 130 may include a temperature-boosting operation and a synthesizing operation. The temperature-boosting operation may include an operation of placing the base substrate 110 where the metal catalyst layer 120 is formed in a chamber that is a thermal reactor, and boosting a temperature inside the thermal reactor from a room temperature to a first temperature. The first temperature may be between about 900° C. to about 1500° C.

In the temperature-boosting operation, a gas including carbon as a carbon source may be injected to the chamber. The carbon source may use a compound with 12 or less carbon atoms or a compound with 4 or less carbon atoms or a compound with 2 or less carbon atoms. Such an example may use one or more selected from a group consisting of methane, ethane, ethylene, ethanol, acetylene, propane, propylene, butane, butadiene, pentane, pentene, cyclophane, tadiene, hexane, cyclohexane, benzene, toluene, and coronene. In the temperature-boosting operation, carbon may be absorbed in the metal catalyst layer 120.

In some embodiments, a vacuum pressure of the chamber in the temperature-boosting operation may be 10⁻³ Torr, and a methane gas CH₄ may be used as a carbon source. The methane gas may be injected as 30 sccm, and may be temperature-boosted from the room temperature to about 1000° C. for 50 minutes.

Thereafter, a synthesizing operation of synthesizing graphene by injecting a carbon source while maintaining the boosted temperature as the temperature of the chamber for a specific time may be performed.

In some embodiments, a time for maintaining the temperature boosted in the synthesizing operation may be about 0.5 to about 2 hours. In some embodiments, the carbon source may be a methane gas. In the synthesizing operation of the graphene layer, induction heating, radiant heat, laser, infrared rays, microwave, plasma, ultraviolet rays, surface plasmon heating, etc., may be used as a heat source of a heat treatment process.

In the temperature-boosting operation and the synthesizing operation, the temperature may be controlled in a range of about 25° C. to about 1500° C., and the time may be about 0.17 hour to about 100 hours. After completion of the synthesizing operation, natural cooling may be performed to complete the graphene synthesizing operation.

The graphene layer 130 synthesized in this way may function as an antioxidant film of the semiconductor package substrate 100 as in the data of FIG. 3, thereby securing the reliability of the semiconductor package substrate 100. Moreover, as the graphene layer 130 is formed, the wire pull strength may be secured without forming a separate plating layer of Au, Ag, etc., on the semiconductor package substrate 100, thereby reducing a cost due to no need to use precious metal.

Although the disclosure has been described with reference to an example shown in the drawings, it will be understood by those of ordinary skill in the art that various modifications and equivalent other examples may be made from the shown example. Accordingly, the true technical scope of the disclosure should be defined by the technical spirit of the appended claims.

As described above, the semiconductor package substrate according to an embodiment of the disclosure uses the graphene layer as the antioxidant film, thereby improving the reliability of the semiconductor package substrate.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

1. A semiconductor package substrate comprising:
a base substrate comprising a die pad portion and a lead portion;
a metal catalyst layer arranged on the base substrate; and
a graphene layer arranged on the metal catalyst layer.

2. The semiconductor package substrate of claim 1, wherein the base substrate comprises a copper (Cu) alloy, and
the metal catalyst layer comprises at least one of Cu, nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt).

3. The semiconductor package substrate of claim 1, wherein the base substrate comprises a copper (Cu) alloy, and
the metal catalyst layer comprises Cu of a purity of 99% or higher.

4. The semiconductor package substrate of claim 1, wherein the metal catalyst layer is continuously arranged to surround a top surface, a bottom surface, and a side surface of each of the die pad portion and the lead portion.

5. The semiconductor package substrate of claim 1, wherein the graphene layer is continuously arranged to surround a top surface, a bottom surface, and a side surface of each of the die pad portion and the lead portion.

6. A semiconductor package comprising:
the semiconductor package substrate of claim 1;
a semiconductor chip arranged on the die pad portion; and
a bonding wire connecting the semiconductor chip with the lead portion,
wherein the bonding wire directly contacts the graphene layer.

7. The semiconductor package of claim 6, wherein a wire pull strength of the bonding wire is about 3.5 gf to about 5 gf.

8. The semiconductor package of claim 6, further comprising a mold resin covering the semiconductor chip and the bonding wire.

9. A method of manufacturing a semiconductor package substrate, the method comprising:
processing a base metal into a base substrate comprising a die pad portion and a lead portion;
forming a metal catalyst layer on the base substrate; and
forming a graphene layer on the metal catalyst layer.

10. The method of claim 9, wherein the base metal comprises a copper (Cu) alloy, and
the metal catalyst layer comprises at least one of Cu, nickel (Ni), silver (Ag), gold (Au), titanium (Ti), cobalt (Co), ruthenium (Ru), rhodium (Rh), palladium (Pd), hafnium (Hf), tantalum (Ta), tungsten (W), rhenium (Re), iridium (Ir), and platinum (Pt).

11. The method of claim 9, wherein the metal catalyst layer is continuously formed to surround a top surface, a bottom surface, and a side surface of each of the die pad portion and the lead portion.

12. The method of claim 9, wherein the graphene layer is continuously formed to surround a top surface, a bottom surface, and a side surface of each of the die pad portion and the lead portion.

13. The method of claim 9, wherein the forming of the graphene layer comprises:
a temperature-boosting operation of placing the base substrate where the metal catalyst layer is formed in a thermal reactor and boosting a temperature inside the thermal reactor to a first temperature; and
a synthesizing operation of injecting a carbon source while maintaining the first temperature after the temperature-boosting operation.

14. The method of claim 13, wherein the first temperature is between about 900° C. to about 1500° C.

15. The method of claim 13, wherein a time for maintaining the first temperature in the synthesizing operation is about 0.5 hour to about 2 hours.
